(19) United States
(12) Patent Application Publication
(10) Pub. No.: US 2024/0422947 A1
(43) Pub. Date: Dec. 19, 2024

(54) HOUSING FOR RECEIVING AN ELECTRICAL HEAT SOURCE

(71) Applicant: Phoenix Contact GmbH & Co. KG, Blomberg (DE)

(72) Inventor: Frank BEST, Bueckeburg (DE)

(21) Appl. No.: 18/706,779

(22) PCT Filed: Nov. 4, 2022
(86) PCT No.: PCT/EP2022/080775

§ 371 Date: May 2, 2024

(30) Foreign Application Priority Data
Nov. 5, 2021 (BE) BE2021/5862

(51) Int. Cl. H05K 7/20

(52) U.S. Cl. CPC H05K 7/20418; H05K 7/20172

(57) ABSTRACT

A housing for housing an electrical heat source includes: a housing base of the housing, an extent of the housing base in a first direction determining a height dimension of the housing; a housing head of the housing facing away from the housing base in a second direction, which housing head has a head dimension in the first direction which is at most 60 percent of the height dimension of the housing; and a heat sink extending in the housing between the housing base and the housing head in the first direction, which heat sink is longer in the first direction than the head dimension and extends in the first direction on one side or on both sides of the housing head to a respective housing opening of the housing, through which the heat sink is in fluid connection with an environment of the housing.

### CROSS-REFERENCE TO PRIOR APPLICATIONS

This application is a U.S. National Phase application under 35 U.S.C. § 371 of International Application No. PCT/EP2022/080775, filed on Nov. 4, 2022, and claims benefit to Belgian Patent Application No. BE 2021/5862, filed on Nov. 5, 2021. The International Application was published in German on May 11, 2023 as WO/2023/079056 under PCT Article 21(2).

### FIELD

The invention relates to the thermal management of electrical heat sources. In particular, a housing for housing an electrical heat source is provided.

### BACKGROUND

Housing for electrical components, such as circuit breakers and programmable logic control systems, often has to be arranged in a compact way. For example, such housings are arranged close together so that a significant part of the housing surface is not available for heat dissipation. Ventilation openings are traditionally provided in the housing to prevent heat build-up from individual electrical heat sources arranged in the housing. An air flow driven through the housing due to thermal convection either passes directly over the heatemitting components or the components are provided with a heat sink, which improves the thermal coupling to the air flow in the housing.

Another strategy for avoiding heat build-up in the housing improves the thermal connection between the heat sink in the housing and the housing wall. The document DE 32 19 571 A1 proposes a thermal connection with mechanical preload between the heat sink in the housing and the inner wall of the housing to improve heat dissipation.

Furthermore, metallic housings are known that also serve as heat sinks in that the housing comprises an internal contact surface against which a heat-emitting component may abut. An example of this is the cast aluminum “RPI CASE ALU08”, which comprises thermal contact surfaces on the inside for the RAM and processor of the “Raspberry Pi 4” single-board computer. However, no terminals for conductors carrying mains voltage or contacts for conductor rails may be provided on a completely metallic housing, which is why such housings are only suitable for low voltages.

As a result, existing housing comprises insufficient heat transfer for higher power densities.

### SUMMARY

In an embodiment, the present invention provides a housing for housing an electrical heat source, comprising: a housing base of the housing, an extent of the housing base in a first direction determining a height dimension of the housing: a housing head of the housing facing away from the housing base in a second direction, which housing head comprises a head dimension in the first direction which is at most 60 percent of the height dimension of the housing; and a heat sink extending in the housing between the housing base and the housing head in the first direction, which heat sink is longer in the first direction than the head dimension and extends in the first direction on one side or on both sides of the housing head to a respective housing opening of the housing, through which the heat sink is in fluid connection with an environment of the housing.

### BRIEF DESCRIPTION OF THE DRAWINGS

The present invention will be described in even greater detail below based on the exemplary figures. The invention is not limited to the exemplary embodiments. Other features and advantages of various embodiments of the present invention will become apparent by reading the following detailed description with reference to the attached drawings which illustrate the following:

FIG. 1A a schematic perspective view of a housing for accommodating an electrical heat source according to a first embodiment:

FIG. 1B a schematic perspective view of a housing for accommodating an electrical heat source according to a first variant of the first embodiment;

FIG. 1C a schematic perspective view of a housing for accommodating an electrical heat source according to a second variant of the first embodiment;

FIG. 2 a schematic perspective view of a housing for accommodating an electrical heat source according to a second embodiment:

FIG. 3A a schematic perspective view of a housing for accommodating an electrical heat source according to a third embodiment:

FIG. 3B a schematic perspective view of a heat sink according to the third embodiment:

FIG. 4 a schematic perspective view of a housing for accommodating an electrical heat source and such a heat source according to a fourth embodiment:

FIG. 5A a schematic perspective view of a fifth embodiment of a heat transport system in a housing for accommodating an electrical heat source, which can be combined with the first, second, third or fourth embodiment:

FIG. 5B a functional representation of the housing according to the fifth embodiment:

FIG. 6A a schematic perspective view of a sixth embodiment of a heat transport system in a housing for accommodating an electrical heat source, which can be combined with the first, second, third or fourth embodiment:

FIG. 6B a functional representation of the housing according to the sixth embodiment:

FIG. 7A a schematic perspective view of a seventh embodiment of a heat transport in a housing for accommodating an electrical heat source, which can be combined with the first, second, third or fourth embodiment:

FIG. 7B a functional representation of the housing according to the seventh embodiment:

FIG. 8 a functional representation of the housing according to an eighth embodiment:

FIG. 9 a schematic perspective view of a ninth embodiment of a housing for accommodating an electrical heat source, which may be additional to the first to eighth embodiments.

### DETAILED DESCRIPTION

In an embodiment, the present invention provides a housing for higher heat dissipation power densities, i.e. a housing with a higher cooling power density. In an embodiment the invention provides a housing that enables an improved rate of passive or active heat dissipation as measured by its small space requirement or compact design.

One aspect relates to a housing for housing an electrical heat source. The housing comprises a housing base. An extent of the housing base in a first direction determines a height dimension of the housing. The housing further comprises a housing head facing away from the housing base in a second direction. The housing head comprises a head dimension in the first direction. The head dimension is at most 60 percent of the height dimension of the housing (for example, less than half of the height dimension of the housing). The housing further comprises a heat sink extending in the housing in the first direction between the housing base and the housing head. The heat sink is longer in the first direction than the head dimension. The heat sink extends in the first direction on one side or on both sides of the housing head to a housing opening of the housing configured between the housing base and the housing head. The heat sink is in fluid connection with an environment of the housing through the housing opening.

The heat sink may project beyond the housing head in the first direction on at least one side.

The heat sink may extend on one side of the housing head to a respective housing opening of the housing configured between the housing base and the housing head, in that the heat sink extends from a position below the housing head (i.e., in the second direction between the housing head and the housing base) in the first direction to a side of the housing where the housing opening is.

Alternatively or additionally, the heat sink may extend on both sides of the housing head to a respective housing opening of the housing configured between the housing base and the housing head, in that the heat sink extends from a first housing opening (of the housing openings of the housing) to a second housing opening (of the housing openings of the housing) opposite the first housing opening in the first direction.

The heat sink may be covered at least in sections by a protective cover (e.g. a cover) on one side of the housing opening or on one of the housing openings on both sides or at both housing openings.

For example, the heat sink may be in fluid communication with an environment of the housing in the first direction on either side of the housing head through at least one housing opening of the housing formed between the housing base and the housing head. Alternatively or additionally, the heat sink may be exposed to the outside on both sides of the housing head through a housing opening of the housing formed between the housing base and the housing head, both in the first direction and in the second direction.

The head dimension may extend in the first direction between (for example, parallel to a third direction) edges of the housing head and/or correspond to a length of a (preferably planar) front surface (i.e., a surface) of the housing head in the first direction. Alternatively or additionally, the height dimension (i.e., the extent of the housing base) may be equal to or less than an outer dimension (for example, a largest dimension) of the housing in the first direction.

The head dimension may be at most half (i.e. less than half or equal to half) of the height dimension of the housing. Alternatively or additionally, the head dimension may be equal to 50% (for example, between 49.4% and 50.6%) or 41% (for example, between 40.5% and 41.4%) or 30% (for example, between 29.7% and 30.3%).

The heat sink may be flush with the housing base in the first direction at the housing openings. For example, one end of the heat sink is flush with the housing base in the first direction. Alternatively, the length of the heat sink in the first direction may be less than the height dimension. For example, one end of the housing base may extend beyond one end of the heat sink in the first direction. Alternatively, the length of the heat sink in the first direction may be greater than the height dimension. For example, one end of the heat sink may extend beyond one end of the housing base in the first direction.

The heat sink may be exposed to the outside on one side or both sides of the housing head through the respective housing opening of the housing in the first direction and/or in the second direction. Herein, the exposure may refer to the exterior (i.e. an environment) of the housing.

By extending the heat sink (for example substantially) over the height dimension of the housing and exposing it at both ends in one or two directions in each case, at least some embodiments may conduct heat from the interior of the housing, where the electrical heat sources are, to the ends of the heat sink and thus out of the housing, to be dissipated there to the ambient air via the effectively large heat exchange surfaces due to the (preferably two-sided) exposure. These embodiments or further embodiments do not rely on heat dissipation at housing faces, such as front faces extending parallel to the first and second directions. Thus, a dense arrangement of such housings (for example, arranged in a row on a mounting rail) does not prevent the effectiveness of the waste heat transport.

These embodiments or further embodiments may meet standardized requirements for the housing shape, for example with regard to the housing head, due to the arrangement of the heat exchange points at the opposite ends of the heat sink in the first direction. These embodiments or further embodiments may meet standardized requirements for the electrical insulation of the housing due to the heat sink passing through the housing. The same or further embodiments of the housing may improve the transport of waste heat from electrical heat sources in the housing without falling below standardized requirements for the shape of the housing and/or for the electrical insulation of the housing.

Embodiments of the housing may achieve a cooling capacity without a large-area heat dissipation outside the housing, which conventional housings only achieve with a large-area heat dissipation outside the housing or a larger housing surface. This enables the housing to absorb electrical heat sources (for example those operated above low voltages) in a more compact volume.

In these embodiments or further embodiments of a constellation according to the invention, the housing head is formed on an outer side. Below (for example in the second direction), a cooling device extends laterally on both sides (for example in the first direction), which comprises at least the heat sink. The housing head may comprise (for example passive or active, i.e. operated) elements for heat transport, e.g. ventilation openings, heat pipes or a fan. Alternatively or additionally, the housing head may comprise (e.g. passive or active) elements of an interface, such as connection terminals or a user interface.

Connection elements, input elements (e.g. switching elements) and/or display elements may be arranged (e.g. removably accommodated or removably received) on the housing head. These (e.g. electrical) elements may be thermally decoupled from the heat sink by the housing head.

In these embodiments or further embodiments, the housing head serves to stiffen the housing. For example, the end faces of the housing (extending in the first and second directions) may be connected to one another via the housing head.

The housing head may be detachable (preferably without tools) or opened, for example to simplify the assembly or maintenance of components in the housing. Alternatively or additionally, lines may be routed via the housing head to connect components arranged at a distance from each other within the housing.

A rear surface of the housing base and a front surface of the housing head may be parallel to each other. This means that the front surface may serve as a user interface or fit flush into a protective cover.

The housing openings of the housing may be arranged in the first direction on either side of the housing head. As a result, the heat sink may be swept over its entire length by an air flow (for example, thermally or mechanically driven) to dissipate heat.

The housing head may be centered in the first direction with respect to the housing and/or arranged centrally with respect to the housing base. This may maximize stiffening of the housing and/or minimize flow paths from a fan in the housing head to the opposite exposed ends of the heat sink.

The housing head may also be referred to as the housing dome (dome for short). The front surface may be a surface of the housing dome.

The second direction may be perpendicular to the first direction.

Herein, the concept of direction may be a spatial direction of extent, i.e., relate to a (for example, linear) spatial dimension. Within this spatial dimension, the concept of direction may comprise one of the two orientations (i.e., a direction in the sense of “aligned” and its opposite direction) or both orientations.

The housing openings may be arranged at opposite ends of the housing in the first direction. This may allow a straight flow through the housing.

The housing may further comprise two opposite end faces of the housing in a third direction, each extending, optionally parallel, to the first direction and the second direction between the housing base and the housing head. The housing openings may be configured between the two end faces. As a result, a flow channel connecting the housing openings may be closed. Alternatively or additionally, the end faces may comprise a step on one or each of the housing openings. This may increase the effective area of the housing openings.

The end faces may extend inclined to the first and/or second directions.

The end faces may be parallel to each other. The end faces may extend between the housing base and the housing head. The end faces may be parallel to the first direction and the second direction and/or perpendicular to the third direction. In the second direction, the end faces may comprise a depth dimension of at least 52 mm and/or a maximum of 55 mm, 70 mm or 92.5 mm (possibly plus a depth of a recess for receiving a mounting rail on the housing base). The shape and/or dimensions of the end faces may correspond (for example in sections) to the shape and dimensions of the heat sink.

The two housing openings may each be bordered by the end faces and/or a collar of the housing head (for example, one that runs around the housing head). This may increase the effective area of the housing openings for heat dissipation.

These embodiments or further embodiments of the housing may be arranged or arrangeable adjacent to one another in meter cabinets and/or on a mounting rail, so that only the housing head (for example through a through recess in a protective cover) is visible or exposed for a user to see and/or operate. As the head dimension is significantly shorter than the height dimension, the opposite ends of the heat sink remain exposed when the housing is installed and covered by the protective cover. For example, the protective cover may be arranged flush with the front surface of the housing head, with the protective cover being spaced from the exposed heat sink in the second direction due to the collar of the housing head. Thus, in the installed state of the housing, the heat sink may be in heat exchange (e.g. convective or radiative) and/or in fluid connection (for convective heat exchange with flow through the housing along the first direction) with the environment at both pending ends towards the first and second direction.

The housing base may be reversibly or irreversibly attached to a mounting rail. Preferably, the housing base may be configured to snap onto a mounting rail.

The mounting rail may be arranged in a switch cabinet (e.g. a switch box, meter cabinet or small distribution cabinet). The housing, the switch cabinet or the combination of the housing in the switch cabinet may fulfill a protection class, for example due to the housing being encapsulated by the switch cabinet. The housing, the switch cabinet or the combination of housing and switch cabinet may, for example, fulfill a protection class II, in which equipment comprises reinforced or double insulation at the level of the rated insulation voltage between active and touchable parts, for example in accordance with the standard DIN VDE 0100, part 410, 412.1.

A third direction may be perpendicular to the first and second directions.

For example, the height dimension may be equal to or greater than 167% of the head dimension. For example, with a head dimension of 45 mm, the height dimension may be at least 75 mm. Optionally, the height dimension may be limited to 90 mm.

The head dimension may be equal to or less than 5%, 10%, 30%, 40% or 50% of the height dimension. The head dimension may comprise a proportion of about 50%, about 40% or about 30% of the height dimension. For example, the head dimension may comprise 45 mm+0.5 mm, and the height dimension may comprise a maximum of 90 mm, 110 mm or 150 mm. Alternatively or additionally, an envelope dimension of the housing (preferably the head dimension and/or the height dimension and/or height sections and/or depth sections of the housing) may comply with DIN 43 880.

The heat sink may overlap the housing head in the first direction by at least half the head dimension.

The length of the heat sink in the first direction may be at least 150 percent of the head dimension. Alternatively or additionally, the length of the heat sink in the first direction may be at least 90 percent of the height dimension. Alternatively or additionally, the heat sink may be adjacent to the housing head or further extend into the housing head.

The heat sink may comprise at least one flow channel via which the housing openings of the housing are in fluid connection. As a result, an air flow (driven thermally or using a fan, for example) may absorb waste heat from the heat sink over the entire height dimension and release it to the environment at one or a plurality of the housing openings.

The heat sink may comprise a depth section extending in the second direction at the at least one housing opening or at opposite ends in the first direction. The heat sink may be exposed to the first direction at the depth sections through the respective housing opening of the housing.

Each of the depth sections may extend parallel to the second direction and third direction. The depth sections of the heat sink may be flush with the housing base. Each of the depth sections may be an end section of the housing and/or the heat sink.

The depth section of the heat sink may be flush with the housing or housing base at one or each of the housing openings in the first direction. Alternatively or additionally, the housing or housing base may project beyond the heat sink at one or each of the housing openings in the first direction.

Alternatively or additionally, the heat sink may not project beyond the housing in the first direction, or only slightly. For example, the heat sink may project beyond the housing in the first direction by no more than 15%, preferably by no more than 10%, of the head dimension.

Alternatively or additionally, the heat sink (in the first direction) may comprise a height section on one side or on both sides of the housing head with an extent in the first direction. The heat sink may be exposed to the second direction at the height sections through the respective housing opening of the housing. Each of the height sections may be a front section of the housing. The front sections may be arranged below the front surface of the housing head in the second direction.

The heat sink may be exposed behind a protective cover on one or each of the height sections.

Exposure may be realized if the heat sink is in fluid connection with the environment (for example, for free convection) and/or in visual contact with the environment (for example, for direct heat radiation), either directly or through grid openings.

The height section or sections of the heat sink may extend parallel to the first direction, and/or wherein the height section or sections of the heat sink may comprise a (rectilinear or curved) extent in the first direction and/or in the second direction. Alternatively or additionally, the height section or sections of the heat sink may extend in a straight line between the first direction and the second direction at an acute angle to the first direction.

Each of the height sections may extend parallel to the first direction and the third direction. Alternatively, each of the height sections may extend diagonally to the first and second directions and parallel to the third direction. As a result, the active surfaces of the heat sink exposed to the second direction may be enlarged.

The depth section(s) and/or the height section(s) may comprise straight or curved edges of the heat sink. The depth section(s) and/or the height section(s) may comprise edges (for example of the fins) of the heat sink. These edges may (for example in sections) be straight, stepped or curved.

The heat sink may comprise a side section in the third direction at one end or at opposite ends, which is exposed to the third direction,

The heat sink may be exposed at the respective side section through a respective housing opening of the housing (for example to the third direction).

Heat exchange surfaces of the heat sink (for example, flow channels configured in the heat sink or at least partially bordered by the heat sink) may be free-form (e.g. rounded or wavy). The heat exchange surfaces may be surfaces of plates, pins and/or wall sections of the heat sink.

The housing head may protrude beyond the height sections in the second direction. This means that the heat sink may be exposed in the second direction even if a cover (such as a protective cover) is flush with the housing head.

The heat sink may be exposed at opposite ends in the first direction, each comprising one of the height sections and one of the depth sections. The height section and the depth section at each end of the heat sink may be collectively referred to as the end section of the heat sink. Alternatively or additionally (for example, at each of the opposite ends), the height section and the depth section may form a step or a step. For example, each depth section may comprise a depth dimension (for example, from the housing base to the step) of a maximum of 44 mm (plus, if necessary, a depth of the recess for receiving the mounting rail).

The housing may comprise a protective grille on one or each of the height sections and/or on one or each of the depth sections and/or on one or each of the side sections (for example, in each case). The protective grille may be arranged on or in the respective housing opening (e.g. removable) or be an integral part of the housing.

The respective housing opening may comprise a plurality of grid openings in the respective protective grid. The heat sink may be in fluid communication with the environment and/or exposed through the grid openings. The heat sink may be in fluid communication with the environment through the grid openings for heat exchange.

The grid openings of the protective grid may correspond to through-openings of the heat sink, for example channel openings of the flow channels of the heat sink (e.g. are in fluid connection in pairs) or are congruent.

The housing may comprise a further housing opening in the housing base. The heat sink may be in fluid communication with the surroundings of the housing and/or exposed through the further housing opening.

The further housing opening may comprise a protective grille with a plurality of grille openings. Through the grille openings, the heat sink may be in fluid communication with the environment and/or exposed.

The heat sink may comprise flow channels that are in fluid connection and/or alignment with both the housing openings opposite in the first direction and the further housing opening.

The flow channels in the heat sink may comprise intersecting rectilinear flow channels. Alternatively or additionally, the heat sink may comprise (for example prismatic) pins that line the rectilinear flow channels (for example on one or both sides). The pins may be straight prisms (for example circular cylinders or cuboids) that extend in the third direction. For example, the flow channels may intersect, resulting in pins (for example of any cross-section) arranged in rows and/or columns (for example matrix-like).

The grid openings may be arranged periodically or randomly. The grid openings may comprise longitudinal slits or circular openings.

One or each of the housing openings may comprise a plurality of grid openings in the protective grid, through which the heat sink is in fluid communication with the environment at one or each of the height sections and/or at one or each of the depth sections and/or at the housing base.

The protective grid may rest on the heat sink, for example on the respective height section and/or the respective depth section and/or the respective side section. Alternatively or additionally, the protective grid may be mounted on edges (for example extending in the first and/or second direction) of the end faces of the housing and/or extend between the edges of the end faces of the housing. Alternatively or additionally, the protective grid may be mounted on an edge (for example extending in the third direction) of the collar of the housing head and/or on an edge (for example extending in the third direction) of the housing base. Alternatively or additionally, the protective grille may extend between the edge of the collar of the housing head and the edge of the housing base.

The protective grid may comprise a perforated plate (i.e. a perforated panel) or a wire mesh.

The housing head may comprise a front surface perpendicular to the second direction and/or a collar (for example completely or partially circumferentially) surrounding the front surface. The collar may extend in the second direction. As a result, components that are thermally decoupled from the heat sink may be arranged in the front surface. The collar may be adjacent to the height sections.

In other words, the head may be arranged on or above the heat sink in the second direction. Alternatively, the heat sink may extend into the housing head (i.e. further extend into the housing head).

The front surface may extend beyond the heat sink and/or the height sections in the second direction according to the extent (i.e. length or depth) of the collar. As a result, the heat sink may be exposed to the second direction even when the cover (for example, a protective cover) is flush with the housing head.

The collar may extend along a second depth dimension. Further housing openings in the collar may establish or improve a fluid connection between the fan and the environment.

The front surface and/or the housing head may be plugged onto the heat sink and/or onto the front sides of the housing (preferably detachably), optionally using the collar. This may make the housing accessible for maintenance from a user side.

Alternatively or additionally, the housing head may be open towards the second direction, i.e. comprise a housing head opening. The housing head opening may be in the front surface or bordered by the collar. The collar may completely or partially surround (i.e. completely or partially surround) the housing head opening.

The collar may be formed by one or a plurality of edges, a frame or one or a plurality of surfaces adjacent to the height sections.

The heat sink may comprise a head section extending into the housing head in the second direction. Optionally, the housing head may comprise a collar extending in the second direction and/or surrounding the head section (for example, completely or partially circumferentially). The collar may mechanically stiffen the housing.

The head portion may be in fluid communication with the environment and/or exposed to the second direction through a housing head opening on the housing head (for example, the housing head opening in the front surface and/or a housing head opening formed and/or rimmed by the collar).

The heat sink may comprise a head section (for example the front surface) on the housing head, which extends in the first direction and the third direction. The heat sink may be exposed at the head section through the housing head (for example through the front surface) to the second direction.

The housing may further comprise a fan arranged in the housing head. Optionally, the fan may be configured to draw in a fluid (for example ambient air) through housing head openings in the housing head and to convey it in the housing along the heat sink to the housing openings opposite in the first direction. Alternatively or additionally, the fan may be configured to draw in a fluid (for example ambient air) from the housing openings opposite in the first direction in the housing along the heat sink and convey it to housing head openings in the housing head.

The fan may comprise any technical means for generating an air flow. The fan may also be referred to as a ventilator.

The fan may comprise a device for generating a fluid flow, in particular for forced convention. For example, the fan is configured to generate an air flow that is directed into the interior of the housing and/or flows out of the housing into the environment.

The fan may be arranged to dissipate the heat absorbed by the heat sink. A heat flow originating from the electrical heat source may diffuse in the heat sink (heat spreading) and be dissipated convectively to the surroundings of the housing due to the flow of ambient air along the heat sink (heat dissipation). Alternatively or additionally, the fan or at least one further fan may be arranged at different locations of the housing (for example at one or each of the housing openings).

The fan may be configured to generate an air flow in the direction of the housing base in order to supply or circulate ambient air to the electrical heat source in the housing, or vice versa.

The housing base and the heat sink base may comprise through openings (for example a perforation) through which the air flow is guided through the housing.

A variant of each embodiment may utilize the chimney effect. One or a plurality of fans may be arranged in the longitudinal direction of the slats (also: ribs) or transverse to them.

The fan may also be arranged inside the housing (for example, inside the housing head) to protect against injury.

The fan (or synonymously: ventilator) may be an axial fan, preferably with its axis parallel to the second direction. The housing head openings may be arranged in a surface of the housing head and/or the front surface perpendicular to the second direction. Alternatively or additionally, the fan may be a centrifugal fan or radial fan, preferably with its axis parallel to the second direction. The housing head openings may be arranged in a surface of the housing head and/or the collar that is perpendicular to the first direction.

The grille openings of the protective grille may correspond to the channel openings of the flow channels of the heat sink or be congruent.

The heat sink may be in fluid communication with the environment through a transverse flow in the second direction (for example, from the housing head to the housing base). The transverse flow transverse to the first direction, together with a longitudinal flow in the first direction, may enable convective heat exchange with the environment.

Alternatively or additionally, the flow channels may be aligned with both the housing openings and the further housing opening, for example in that the flow channels comprise at least one flow channel extending in the first direction and at least one flow channel extending in the second direction, which intersect (optionally within the heat sink).

The heat sink may comprise mutually parallel plates (for example fins) and/or pins and/or wall sections. All or some of the plates may extend parallel to the first direction and the third direction. Alternatively or additionally, all or some of the plates may each extend parallel to the second direction and third direction. The pins may each extend parallel to the second or third direction. The heat sink may comprise a plurality of the plates at each of the opposing depth sections and/or the height sections.

The flow channels may be configured (for example in sections) within the heat sink and/or between the plates (for example between the fins) or wall sections or pins of the heat sink and/or between the heat sink (for example two adjacent plates) and the housing (for example the front faces).

The heat sink may comprise at least one group of mutually parallel plates and/or pins and/or wall sections.

The plates and/or wall sections may each extend parallel to the first direction and the third direction, or each extend parallel to the first direction and the second direction, or each extend parallel to the second direction and the third direction. Alternatively or additionally, the pins may each extend parallel to the second direction or each extend parallel to the third direction or each extend parallel to the first direction.

In the case of a plurality of groups, the above may apply to each group.

The flow channel or channels extending in the first direction may be configured between the plates and/or wall sections, each extending parallel to the first direction and the third direction, or each extending parallel to the first direction and the second direction. Alternatively or additionally, the flow channel or channels extending in the second direction may be configured between the plates and/or wall sections, each extending parallel to the first direction and the second direction or each extending parallel to the second direction and the third direction.

The flow channel or channels extending in the first direction may be configured between the pins, each of which extends parallel to the second direction or each of which extends parallel to the third direction. Alternatively or additionally, the flow channel or channels extending in the second direction may be configured between the pins, each of which extends parallel to the third direction or each of which extends parallel to the first direction.

A cross-sectional shape of at least one or each of the pins may be round or angular (for example polygonal). Alternatively or additionally, at least one or each of the pins may be cylindrical or the cross-section of the pin may vary along the length of the pin.

Alternatively or additionally, the cooling pins may be arranged (for example evenly or regularly) in rows and/or columns (for example in the manner of a matrix) or a section of a Bravais lattice (for example a hexagonal lattice).

The heat sink may comprise one or a plurality of flow channels that are in fluid connection and/or alignment with both the housing openings opposite in the first direction and the further housing opening.

Alternatively or additionally, the heat sink may comprise one or a plurality of flow channels that are in fluid connection and/or alignment with the housing openings opposite in the first direction (and optionally also with the further housing opening). For example, the channel openings of the flow channels may correspond to the grid openings of the housing openings.

For example, the heat sink may comprise a heat sink base on which the mutually parallel plates (for example fins) and/or pins and/or wall sections protrude, for example on one side or both sides of the heat sink base. The heat sink base may be parallel to the first direction and to the third direction. Alternatively or additionally, the heat sink base may be parallel to the second direction and the third direction. The plates (for example the fins) may be parallel to the first direction and to the second direction. Alternatively or additionally, the plates (e.g. the fins) may be parallel to the second direction and the third direction.

The heat sink base and/or one or each plate (for example, a peripheral plate) of the heat sink may be in thermal contact with the electrical heat source or configured to be brought in thermal contact with the electrical heat source.

The heat sink base may also be referred to as the base. The plates (e.g. fins) may extend from the heat sink base. The heat sink base may be formed on one side of the heat sink or the fins may extend from the heat sink base on both sides of the heat sink base.

As an alternative or in addition to the heat sink base, the plates and/or pins and/or wall sections of the heat sink that are parallel to each other may be enclosed on the housing.

The electrical heat source (e.g. a hotspot or hotspot element) may be thermally coupled to the heat sink base and/or to a plate (e.g. fin) of the heat sink.

Alternatively or additionally, the fins may comprise recesses (for example by milling). The heat sink may comprise at least one plate (i.e. a full-surface wall) and/or a wall with recesses or slots (for example pins). For example, the heat sink may comprise fins that are narrower than they are long. Alternatively or additionally, the heat sink may comprise an arrangement of pins and/or wall fragments.

The heat sink may comprise a recess to accommodate or receive a circuit carrier as the electrical heat source, for example a circuit board and/or a system-on-a-module (SOM).

The electrical heat source (for example the SOM) may be arranged at the base of the heat sink or on a wall pending from it (for example on the side of the heat sink) and/or be in thermal contact with the heat sink.

The electrical heat source (e.g. a hotspot of the SOM) is thermally coupled or can be coupled to the heat sink. Optionally, the electrical heat source is arranged between the fins. Alternatively or additionally, the electrical heat source is arranged under the heat sink base. Alternatively or additionally, the electrical heat source (or another electrical heat source) is arranged next to an outer (i.e. peripheral) fin (also: outer fin).

In a variant of each embodiment, not only one circuit carrier (for example, not only one SOM) may be thermally coupled to the heat sink and/or arranged on the heat sink. For example, a plurality of levels of circuit carriers may thermally contact the heat sink at one or more locations.

The housing head may project beyond the height sections in the second direction.

The housing and/or the heat sink may comprise an exposed step (also: step) at each of the two housing openings of the housing. Each of the two steps may comprise one of the depth sections and one of the height sections (for example as a step).

The height sections of the heat sink (for example on both sides of the housing head) may be exposed over their entire width in the third direction. Alternatively or additionally, the depth sections (for example at the housing openings opposite in the first direction) may be exposed over their entire width in the third direction.

The housing head opening may be arranged behind a protective cover or partial cover. Alternatively or additionally, the housing head opening may comprise a protective grille. The protective grille may comprise grille openings that optionally correspond to through openings in the heat sink.

The heat sink may comprise at least one channel opening of a flow channel at each of the height sections. Optionally, one or each channel opening may extend continuously from the height section to the depth section. Alternatively or additionally, the heat sink may comprise at least one channel opening of a flow channel at each of the opposing depth sections. Optionally, one or each channel opening may extend continuously from the depth section to the height section.

The channel openings of the heat sink may be in fluid communication in the housing along one or each flow channel of the heat sink (for example, inside or at the edge of the heat sink).

The heat sink may comprise a plurality of recesses for holding a plurality of circuit carriers. For example, the heat sink may comprise a plurality of parallel recesses, each configured to accommodate or receive a circuit carrier. Alternatively or additionally, the heat sink may comprise at least two recesses arranged at an angle to one another, in particular perpendicularly, each configured to receive a circuit carrier. For example, a first circuit carrier may be arranged parallel to the first and third directions, and/or a second circuit carrier may be arranged parallel to the first and second directions of the housing. For example, the second circuit carrier may comprise a contact strip that is pluggable into a slot of the first circuit carrier.

The recess may be a slot extending in the first direction. Heat-emitting components of the circuit carrier accommodated or received in the slot may be in direct thermal contact with the heat sink or can be brought into such contact.

The heat sink may comprise at least one channel opening at one or each of the height sections. Each of the at least one channel opening may be an end of the flow channel or one of the flow channels of the heat sink. The at least one channel opening may in each case extend continuously from the height section to the depth section, for example over an edge of the step. Alternatively or additionally, the heat sink may comprise at least one channel opening at one or each depth section. Each of the at least one channel opening may be an end of a flow channel of the heat sink. The at least one channel opening may extend continuously from the depth section to the height section, for example over an edge of the step.

The heat sink may comprise a flow channel in the housing between adjacent plates (e.g. fins), via which the at least one channel opening at each of the pending end sections is in fluid connection.

The at least one channel opening may extend in the second direction at the opposing depth sections. Alternatively or additionally, the at least one channel opening may extend at the height sections in the first direction. In this case, the channel opening may extend (for example substantially) in the said direction if a length of the channel opening in the said direction is greater than a length of the channel opening transverse to the said direction.

The heat sink, optionally each of the plates or fins of the heat sink, may extend continuously in the housing along the first direction. Alternatively or additionally, the heat sink, optionally each of the plates or fins of the heat sink, may be integral-one-piece. As a result, a smooth flow channel with low flow resistance and/or a thermal bridge with low thermal resistance may be configured (in one or each of the options) between the housing openings.

The heat sink may be metallic. The heat sink may comprise copper or aluminum.

The housing base may comprise a recess (for example on a rear surface of the housing base) which is configured to receive a section of the mounting rail in a detachable, optionally lockable, manner.

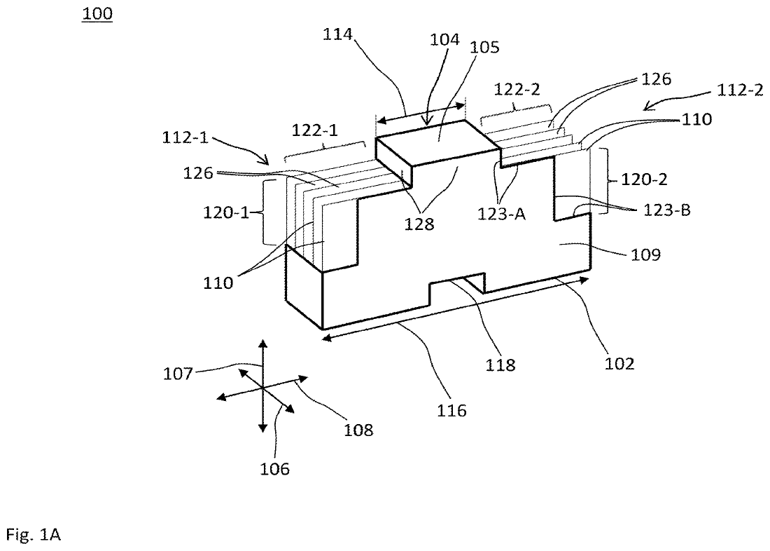

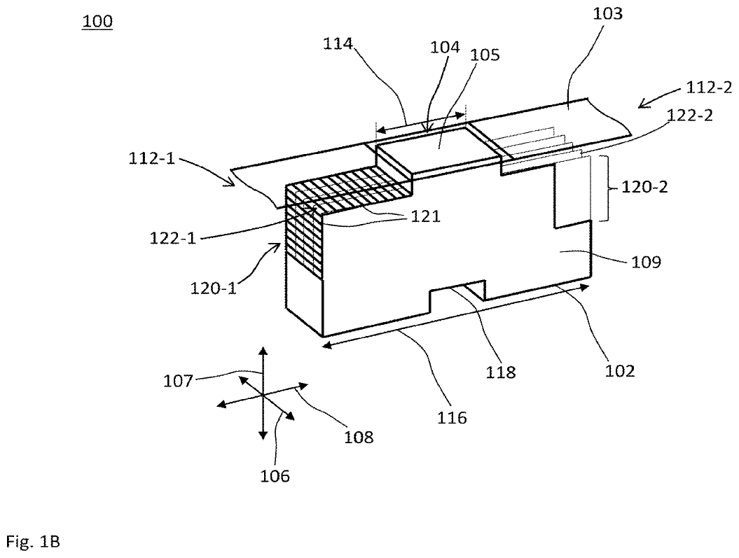

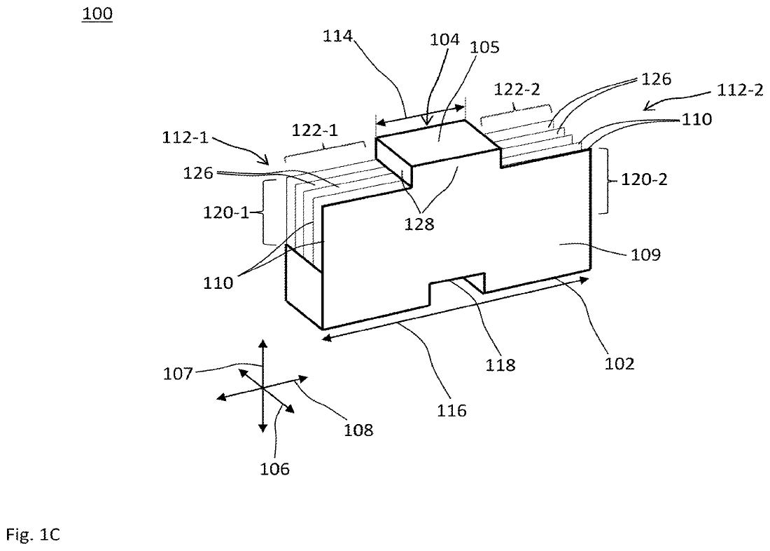

FIG. 1A shows a first embodiment of a housing, generally designated by reference numeral 100, for accommodating an electrical heat source.

The housing 100 comprises a housing base 102 of the housing 100, wherein an extent of the housing base 102 in a first direction 108 determines a height dimension 116 of the housing 100.

The housing 100 further comprises a housing head 104 of the housing 100 facing away from the housing base 102 in a second direction 107, the housing head comprising a head dimension 114 in the first direction 108. The head dimension 114 is at most 60 percent of the height dimension 116 of the housing 100, for example less than or equal to half of the height dimension 116 of the housing 100.

Further, the housing 100 comprises a heat sink 110 extending in the first direction 108 between the housing base 102 and the housing head 104 in the housing 100, the heat sink 110 being longer in the first direction 108 than the head dimension 114. For example, the heat sink 110 is as long as (or longer than) the height dimension 116 of the housing 100 in the first direction 108.

On either side of the housing head 104 is a housing opening 112-1 and 112-2, respectively, of the housing 100 formed between the housing base 102 and the housing head 104. Through each of the housing openings 112-1 and 112-2, the heat sink 110 is in fluid communication with the surrounding environment. In one embodiment, through each of the housing openings 112-1 and 112-2 (which are also referred to as opposing housing openings), the heat sink 110 is exposed to both the first direction 108 and the second direction 107.

The housing openings 112-1 and 112-2 of the housing 100 may each be arranged in the first direction 108 on either side of the housing head 104. The housing openings 112-1 and 112-2 may be arranged at opposite ends of the housing 100 in the first direction 108.

The housing head 104 may be centered in the first direction with respect to the housing 100 and/or may be arranged centrally with respect to the housing base 102.

A front surface 105 of the housing head 104 may comprise the head dimension 114 in the first direction 108. Optionally, the front surface 105 of the housing head 104 is closed.

The housing 100 may further comprise two opposite end faces 109 in a third direction 106, each extending parallel to the first direction 108 and the second direction 107. The housing openings 112-1 and 112-2 may be bordered in sections by the end faces 109.

The first direction 108 and the second direction 107 may be perpendicular to each other. The third direction 106 may be perpendicular to the first direction 108 and the second direction 107.

The head dimension 114 may be a fraction of the height dimension 116. The housing shape, for example the head dimension of 45 mm+0.5 mm and/or the height dimension of (for example maximum) 90 mm, 110 mm or 150 mm may comply with a standard, for example DIN 43 880.

The heat sink 110 may comprise, at opposite ends in the first direction 108, a respective depth section 120-1 or 120-2 extending in the second direction 107. For example, an edge of a plate (such as a fin) of the heat sink 110, or a plurality of edges of the plates or fins of the heat sink 110, may extend at the depth sections 120-1 and 120-2, respectively, in the second direction 107. Each of the depth sections 120-1 and/or 120-2 may extend parallel to the second direction 107 and the third direction 106. For example, a plurality of edges of the plates or fins each extending in the second direction 107 may be arranged flush at the depth sections 120-1 or 120-2 in the third direction 106.

The heat sink 110 may be exposed at the depth sections 120-1 and 120-2 through the respective housing opening 112-1 and 112-2 of the housing 100 toward the first direction 108. In other words, when viewed parallel to the first direction 108, the depth sections 120-1 and 120-2 of the heat sink 110 are exposed on the housing 100.

The heat sink 110 may comprise a height section 122-1 or 122-2 on either side of the housing head 104 (for example, adjacent to the housing head 104 in the first direction 108). Here, reference numerals ending in “−1” may refer to the left or negative half-space of the first direction 108, and reference numerals ending in “−2” may refer to the right or positive half-space of the first direction 108.

The height section 122-1 or 122-2 may extend in the first direction 108. For example, an edge of a plate (for example, a fin) of the heat sink 110, or a plurality of edges of the plates or fins of the heat sink 110, at the height section 122-1 and/or 122-2 may extend in the first direction 108. Each of the height sections 122-1 and/or 122-2 may extend parallel to the first direction 108 and third direction 106. For example, a plurality of edges of the plates or fins each extending in the first direction 108 may be arranged flush at the height section 122-1 or 122-2 in the third direction 106.

The heat sink 110 may be exposed at the height sections 122-1 and 122-2 through the respective housing opening 112-1 and 112-2 of the housing 100 toward the second direction 107. In other words, when viewed parallel to the second direction 107, the height sections 122-1 and 122-2 of the heat sink 110 are exposed on the housing 100.

The height sections 122-1 and/or 122-2 of the heat sink 110 may extend parallel to the first direction 108.

In any embodiment, the heat sink 110 may be exposed at a height section 122-1 or 122-2, or at both height sections 122-1 and 122-2, behind a (for example, closed) protective cover 103. For example, the air may flow between the respective height section 122-1 or 122-2 and the protective cover 103 in the first direction 108 and/or the third direction 106. For example, the protective cover 103 is spaced from the heat sink 110 for rear ventilation.

The protective cover 103 may be part of the housing 100 (for example a housing wall of the housing 100) or an additional loose part. The protective cover 103 may be a cover (for example a clip-on cover).

FIG. 1B shows a variant of the first embodiment with protective cover 103. While the protective cover 103 is limited to the width of the housing 100 in the third direction 106 for simplified illustration, in a variant of each embodiment the protective cover 103 may extend over a plurality of housings 100 (for example arranged side by side in the third direction 106).

For example, the protective cover 103 is spaced from the respective height section 122-1 and 122-2 and/or parallel to the respective height section 122-1 and 122-2. Preferably, the protective cover 103 is flush (in the second direction 107) with the front surface 105 and/or flush with the head section 104.

In any embodiment, the heat sink 110 may be exposed at a height section 122-1 or 122-2, or at both height sections 122-1 and 122-2, and/or at a depth section 120-1 or 120-2, or at both depth sections 120-1 and 120-2, behind a protective grid 121. The protective grid 121 comprises a plurality of grid openings (for example, a perforation and/or ventilation openings) through which the heat sink 110 is in fluid communication with the environment and optionally exposed.

The grille openings of the protective grille 121 may correspond to the flow channels 126 of the heat sink 110 or correspond to them, for example be congruent. For example, the housing openings and/or the grille openings in the housing may correspond to the channel openings of the flow channel(s) of the heat sink. Alternatively or additionally, the grid openings of the protective grid 121 may comprise slots that extend parallel or perpendicular (as shown as an example in FIG. 1B) to the plates of the heat sink 110.

The protective grille 121 may abut directly against the heat sink 110, for example in contrast to a closed protective cover 103, which is spaced from the heat sink and thus allows air circulation between the protective cover 103 and the heat sink 110 at the respective housing opening 112-1 or 112-2.

A step of the end faces 109 and/or a step of the heat sink 110 may comprise (for example along the first direction 108) one or a plurality of steps. Step or step may here mean that a depth dimension (for example of the end faces 109 and/or of the heat sink 110) in the second direction 107 (for example relative to the housing base 102) becomes smaller stepwise (i.e. discontinuously or abruptly) along the first direction 108, for example originating from the housing head 104 in the direction of the respective housing opening 112-1 or 112-2.

In the first embodiments shown in FIGS. 1A and 1B, the end faces 109 of the housing 100 comprise two steps at each housing opening 112-1 and 112-2, namely a first step 123-A at a collar 128 of the housing head 104 and a second step 123-B at the respective depth section 120-1 and 120-2.

FIG. 1C shows a variant of the first embodiment, in which the housing 100 comprises a step at each housing opening 112-1 and 112-2. This variant can also be realized for any other embodiment.

Alternatively or additionally, in a variant of each embodiment, the step in the end faces 109 of the housing 100 may be congruent with the step in the heat sink 110. In other words, the step in the end faces 109 of the housing 100 and the step in the heat sink 110 may be congruent when viewed from the third direction 106. FIG. 1C shows an embodiment in this regard.

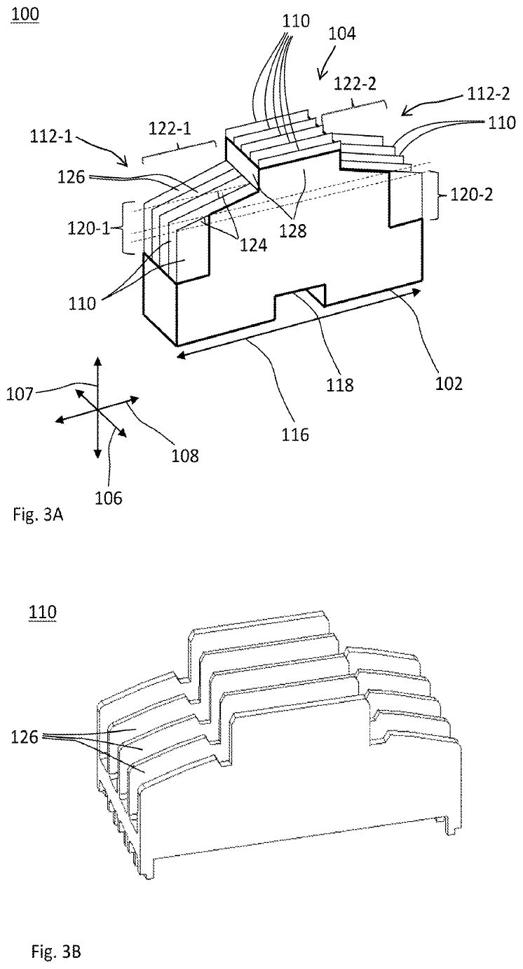

Alternatively or additionally, in a variant of each embodiment, the heat sink 110 may form the housing head 104 or extend into the housing head 104. In this regard, the housing head 104 may comprise a corresponding step at the edges (for example extending in the third direction 106) of the housing head 104. FIGS. 3A and 3B show an embodiment in this regard.

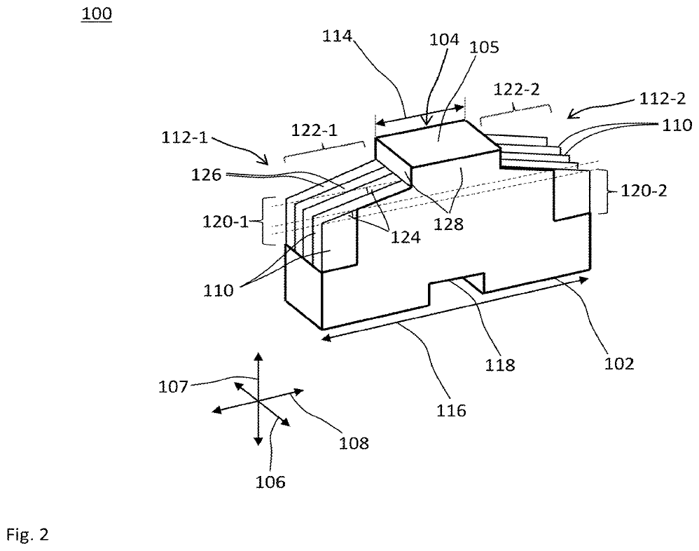

FIG. 2 shows a second embodiment of the housing 100, which may further form or modify features of the first embodiment. Features of FIG. 2 provided with corresponding reference numerals as in one of FIG. 1A, 1B or 1C of FIG. 2 may correspond to those of FIGS. 1A to 1C or can be functionally interchangeable.

The height sections 122-1 and/or 122-2 of the heat sink 110 may include an acute angle 124 with the first direction 108.

In any embodiment, the housing head 104 may extend beyond the height sections 122-1 and 122-2 in the second direction 107. Alternatively or additionally, the housing head 104 may comprise a front surface perpendicular to the second direction 107 and/or a collar 128 (for example, surrounding the front surface) that extends in the second direction 107. The collar 128 may have its sides adjacent to the height sections 122-1 and 122-2 with respect to the first direction 108.

The front surface may extend beyond the heat sink 110 and/or the height sections 122-1 and 122-2 in accordance with the extent of the collar 128 in the second direction 107.

FIG. 3A shows a third embodiment of the housing 100, which may further form or modify features of the first and/or second embodiment. Reference numerals corresponding to those in FIG. 1A to 1C, and/or FIG. 2 may be identical to those of FIGS. 1A to 1C and/or FIG. 2 or can be functionally interchangeable.

The heat sink 110 may comprise a head portion 104 exposed on the housing head 104 towards the second direction 107. The housing head 104 may comprise a collar 128 extending in the second direction 107 and/or surrounding the head portion. Optionally, a fan is arranged on the exposed head portion.

FIG. 3B shows an embodiment of the heat sink 110 with a head portion extending into or forming the housing head 104.

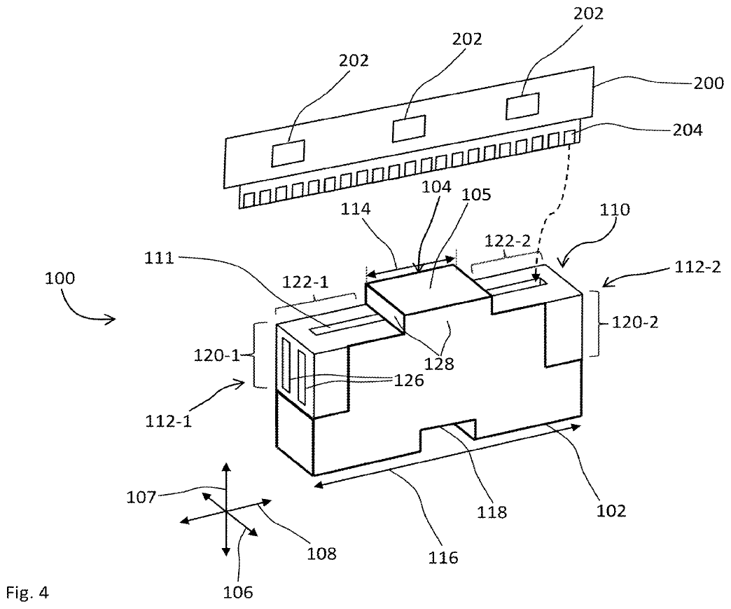

FIG. 4 shows a fourth embodiment of the housing 100, which may further form or modify features of the first, second and/or third embodiment. Features of FIG. 4 provided with corresponding reference numerals as in one of FIGS. 1A to 3B of FIG. 4 may correspond to those of FIGS. 1A to 3B or be functionally interchangeable.

The heat sink 110 may comprise at least one recess 111 for receiving a circuit carrier 200 (for example, a circuit board 200) comprising at least one electrical heat source 202. A system-on-a-module (SOM) or a single-row or double-row memory module (technically also referred to as a single inline memory module, SIMM, or dual inline memory module, DIMM) are examples of the circuit carriers 200.

A solid heat sink 110 may comprise recess 111, as shown schematically in FIG. 4. Alternatively or additionally, the recess 111 may correspond to a space, such as a flow channel 126, between adjacent plates or fins of the heat sink 110, as shown, for example, in each of FIGS. 1 to 3.

The heat sink 110 may comprise at least two recesses 111 arranged perpendicular to each other, each configured to receive a circuit carrier. A first circuit carrier may be arranged parallel to the first direction 108 and third direction 106, for example to accommodate a motherboard. A second circuit carrier 200 may be arranged parallel to the first direction 108 and second direction 107 of the housing 110. For example, the second circuit carrier 200 may comprise a contact strip 204 that is pluggable into a slot of the first circuit carrier.

The recess 111 may be a slot extending in the first direction 108. Heat-emitting components 202 of the circuit carrier 200 received in the slot 111 may be in a thermally conductive connection (for example, a direct thermal contact) with the heat sink 110 or may be configured to be brought in such connection. The heat sink 110 may be in contact with the electrical heat sources 202 for heat conduction, for example directly or via a heat paste.

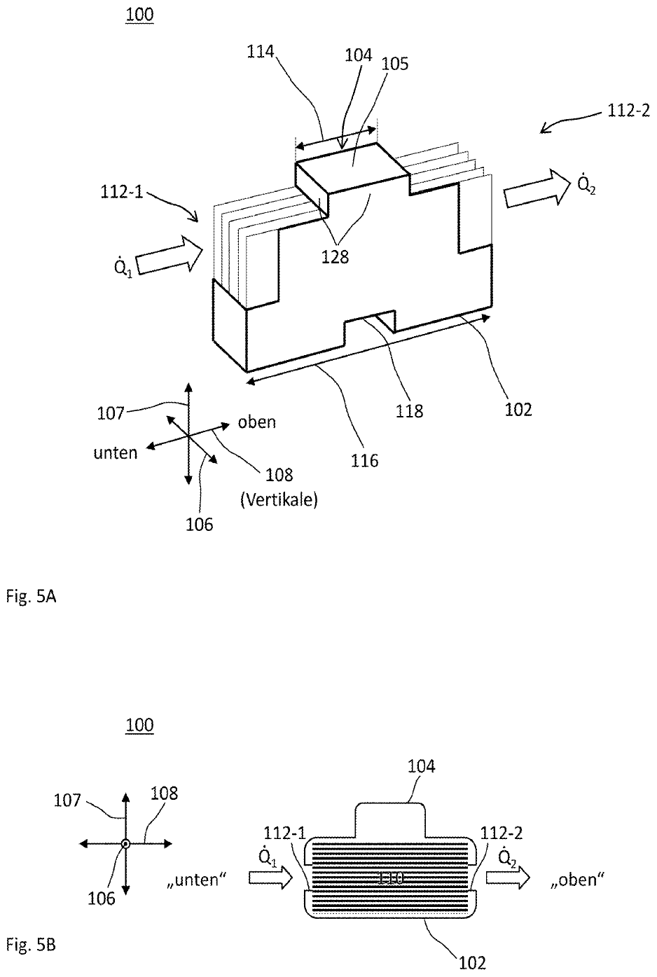

FIG. 5A schematically shows a fifth embodiment of the heat transport using the housing 100, which may adopt or further form features of the first, second, third and/or fourth embodiment. With corresponding reference numerals as in one of FIGS. 1A to 4 may correspond to those of FIGS. 1A to 4 or be functionally interchangeable.

The heat transport, \dot{Q}, at a determined location of the housing 100 is the amount of heat Q transported through this location per time. The heat transport \dot{Q} may comprise contributions due to at least one of the following transport mechanisms: Convection, thermal radiation and conduction.

The heat transport through the (for example lower) housing opening 112-1 of the housing is \dot{Q}₁. The heat transport through the (e.g. upper) housing opening 112-2 of the housing is \dot{Q}₂.

The heat transport shown schematically in FIG. 5A is passive. For example, the heat transport comprises the convection of a fluid (for example air or a liquid or gaseous coolant) driven by a pressure gradient due to a temperature difference between an internal temperature inside the housing 100 and a smaller ambient temperature outside the housing 100. While the mass flow of the fluid at the housing openings 112-1 and 1122 of the housing is the same (at least on average over time), the heat transport \dot{Q}₂ out of the housing is greater than the heat transport \dot{Q}₁ into the housing 100:

\dot{Q}₂>\dot{Q}₁.

This also applies to the sum of heat transport due to other transport mechanisms.

The heat sink 110 may comprise plates (for example, fins on a heat sink base) extending in the first direction 108 and the second direction 107, as shown, for example, in FIG. 5A.

FIG. 5B shows a variant of the fifth embodiment. The heat sink 110 may comprise plates (for example, fins on a heat sink base) extending in the first direction 108 and third direction 106, as shown, for example, in FIG. 5B.

Alternatively or additionally, the housing openings 112-1 and 112-2 may be in fluid communication with the environment only to the first direction 108, as shown, for example, in FIG. 5B.

The housing 100 may further comprise a fan 130 disposed in the housing head 104. The fan 130 may be configured to draw in a fluid (for example ambient air or a liquid or gaseous coolant) through housing head openings in the housing head 104 and to convey it in the housing 100 along the heat sink 110 (in particular in the first direction 108) to the housing openings 112-1 and 112-2 arranged at opposite ends in the first direction 108.

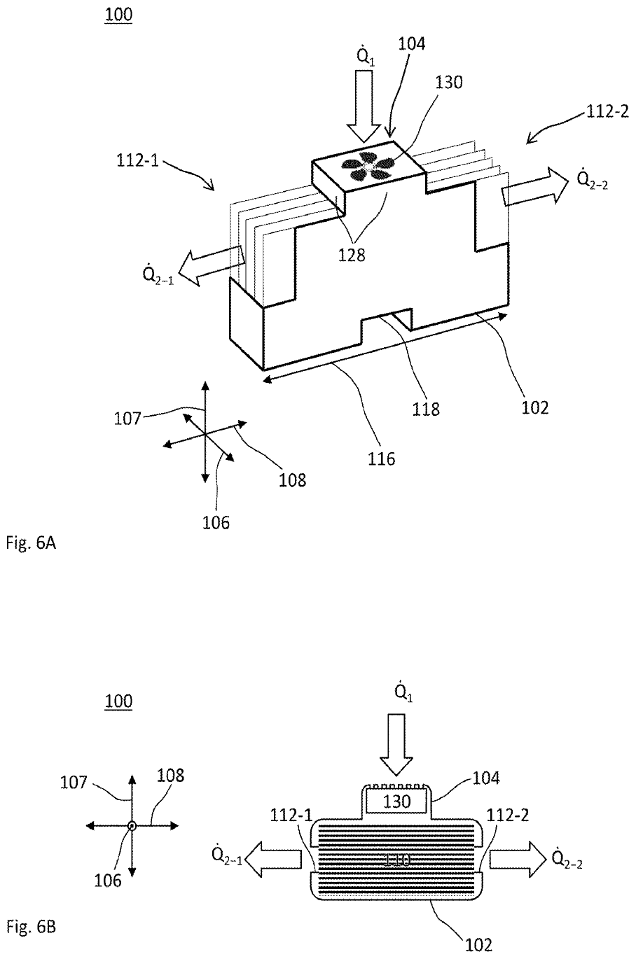

FIG. 6A shows a sixth embodiment of the heat transport using the housing 100, which may adopt or further form features of the first, second, third and/or fourth embodiment. With corresponding reference numerals as in one of FIGS. 1A to 5B of FIG. 6A may correspond to those of FIGS. 1A to 5B or can be functionally interchangeable.

The heat transport shown schematically in FIG. 6A is active, i.e. comprises forced convection driven by power supply, namely using the fan 130. While the sum of the outgoing mass flows of the fluid at the housing openings 112-1 and 112-2 coincides with the incoming mass flow at the housing head openings of the housing head 104 (at least on average over time), the heat transport \dot{Q}₂₋₁ and \dot{Q}₂₋₂ out of the housing 100 is greater than the heat transport \dot{Q}₁ into the housing 100 at the housing head 104:

$${\dot{Q}}_{2 - 1} + {\dot{Q}}_{2 - 2} > {\dot{Q}}_{1} .$$

This also applies to the sum of heat transport due to other transport mechanisms.

The fan 130 is an axial fan whose impeller axis is parallel to the second direction 107. The housing head openings may be arranged in a surface of the housing head (for example, the front surface) perpendicular to the second direction 107.

In any embodiment, the heat sink 110 may comprise plates (for example, fins on a heat sink base) extending in the first direction 108 and second direction 107, as shown, for example, in FIG. 6A, or extending in the first direction 108 and third direction 106, as shown, for example, in FIG. 6B. Alternatively or additionally, the housing openings 112-1 and 112-2 may be in fluid communication with the environment only to the first direction 108, as shown, for example, in FIG. 6B.

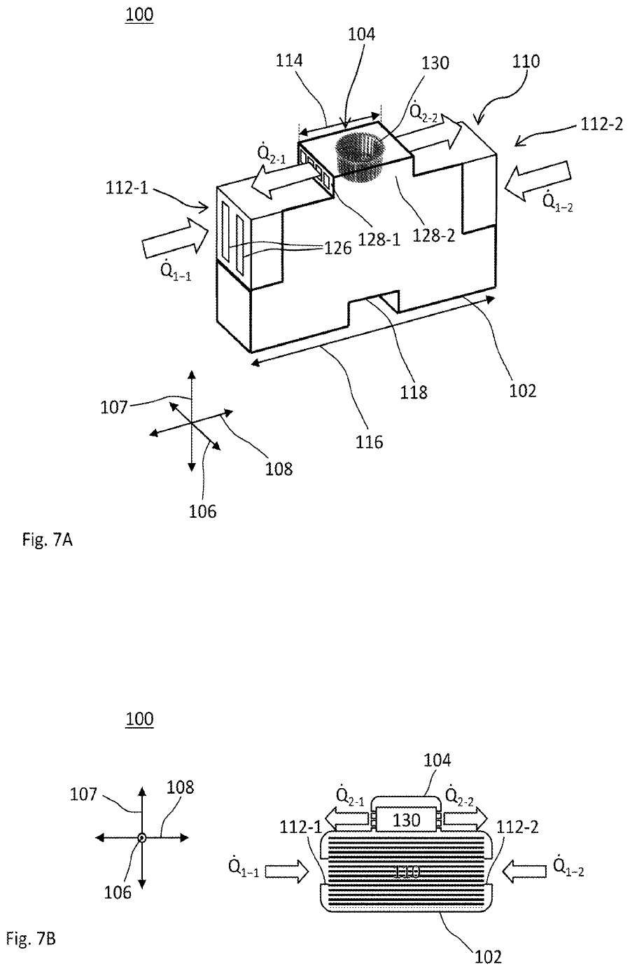

FIG. 7A shows a seventh embodiment of the heat transport using the housing 100, which may adopt or further form features of the first, second, third and/or fourth embodiment. With corresponding reference numerals as in one of FIGS. 1A to 6B of FIG. 7 may correspond to those of FIGS. 1A to 6B or be functionally interchangeable.

The heat transport shown schematically in FIG. 7A is also active, i.e. forced using the fan 130. The fan 130 draws the fluid (for example, ambient air) from the housing openings 112-1 and 112-2 opposite each other in the first direction 108 through the housing 100 along the heat sink 110 and expels it at housing head openings in the housing head 104. In order to allow the housing 100 to be closely aligned, the housing head openings preferably face the first direction 108.

While the sum of the mass flows of the fluid entering the housing 100 at the housing openings 1121—and 1122 coincide—with the mass flow exiting—at the housing head openings of the housing head 104 (at least on average over time), the sum of the heat transport entering the housing 100 \dot{Q}₂₋₁ and \dot{Q}₂₋₂ is greater than the heat transport leaving the housing 100 at the housing head 104 \dot{Q}₁₋₁+\dot{Q}₁₋₂:

$${\dot{Q}}_{2 - 1} + {\dot{Q}}_{2 - 2} > {\dot{Q}}_{1 - 1} + {\dot{Q}}_{1 - 2} .$$

This also applies to the sum of heat transport due to other transport mechanisms.

The fan 130 is a centrifugal fan or radial fan whose impeller axis is parallel to the second direction 107. The housing head openings may be arranged in a surface 128-1 of the housing head and/or the collar 128 perpendicular to the first direction 108. A surface 128-2 of the collar 128, which may be adjacent to an adjacent housing, is closed in a fluid-tight manner.

In any embodiment, the heat sink 110 may comprise plates (for example, fins on a heat sink base) extending in the first direction 108 and second direction 107, or extending in the first direction 108 and third direction 106, as shown, for example, in FIG. 7B. Alternatively or additionally, the housing openings 112-1 and 112-2 may be in fluid communication with the environment and/or exposed only to the first direction 108, as shown, for example, in FIG. 7B.

The heat sink 110 may comprise two or a plurality of plates (for example fins) parallel to each other, each extending parallel to the first direction 108 (and preferably to the second direction 107). The heat transport may be guided due to the plates or the fins (for example along the first direction 108). For example, a flow channel may be configured between adjacent plates or fins and/or between the heat sink 110 and the end face 109, via which the housing opening 112-1 and 112-2 are in fluid communication.

In any embodiment, heat conduction of the (for example metallic) heat sink 110 may contribute to heat transport in the first direction 108 and/or across the height dimension 116 in addition to convection (for example passive or forced using a fan). The heat sink may comprise copper or aluminum.

In any embodiment, the housing base 102 may comprise (for example, on a rear surface of the housing base 102) a recess 118 configured to releasably, optionally lockably, receive a section of mounting rail (for example, a top-hat rail).

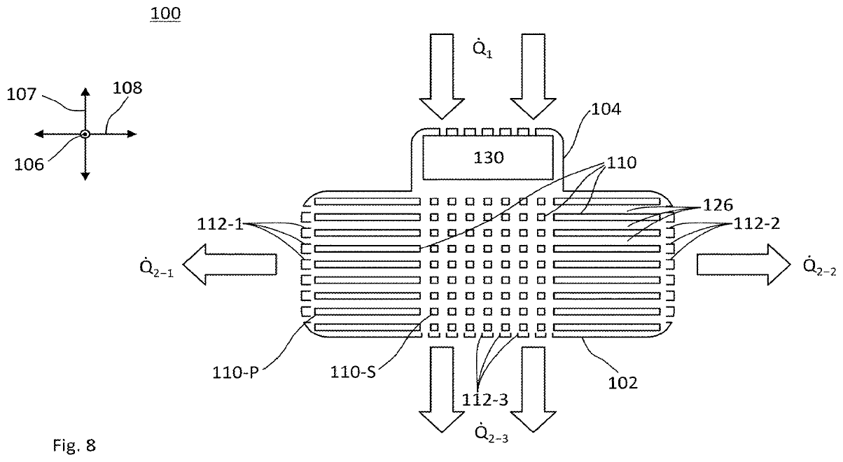

FIG. 8 schematically shows an eighth embodiment of the housing 100. The housing base 102 of the housing 100 comprises one or a plurality of further housing openings 112-3, for example grille openings of a protective grille on the housing base 102. Alternatively or additionally, the heat sink may comprise flow channels 126 (for example in its interior) that are in fluid communication and/or alignment with both the grille openings 112-1 and 112-2 pending in the first direction 108 and the grille openings 112-3 on the further housing opening of the housing base 102. For example, the flow channels 126 cross each other several times in the first direction 108 and the second direction 107, so that the flow channels 126 comprise straight flow channels lined by wall sections or pins 110-S.

Optionally, the pins 110-S are arranged in an area of the heat sink 110 in which a projection of the further housing openings 112-3 in the second direction 107 and a projection of the housing openings 112-1 and 112-2 in the first direction 108 overlap. Alternatively or additionally, the heat sink 110 comprises plates 110-P outside the overlapping area, each of which is aligned with one of the grid openings at the pending housing opening 112-1 or 112-2.

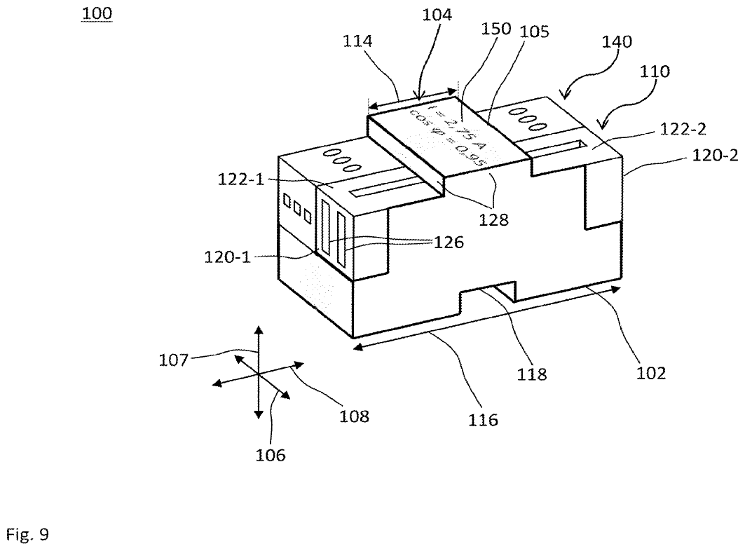

FIG. 9 schematically shows a ninth embodiment of the housing 100. A functional unit 140, for example a programmable logic controller (PLC) or a circuit breaker (CB), is arranged in the housing 100.

A shape of the heat sink 110, for example its depth sections 120-1 and 120-2 and/or its height sections 122-1 and 122-2, may be flush with the functional unit 140, which is preferably adjacent in the third direction 106. For example, the functional unit 140 comprises screw terminals (for example flush with the height sections 122-1 and/or 122-2 in continuation of the third direction 106) for connecting input or output lines (for example flush with the depth sections 120-1 and/or 120-2 in continuation of the third direction 106).

Alternatively or additionally, a display 150 on the housing head 104, the display surface of which is preferably perpendicular to the second direction 107, may extend in the third direction 106 from the heat sink 110 to the functional unit 140.

As can be seen based on the above embodiments, a combination of housing shape and heat sink arrangement according to the invention may result in as yet unexplored advantages.

While the invention has been illustrated and described in detail in the drawings and foregoing description, such illustration and description are to be considered illustrative or exemplary and not restrictive. It will be understood that changes and modifications may be made by those of ordinary skill within the scope of the following claims. In particular, the present invention covers further embodiments with any combination of features from different embodiments described above and below. Additionally, statements made herein characterizing the invention refer to an embodiment of the invention and not necessarily all embodiments.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMERALS

Housing 100
Housing base of the housing 102
Partial cover, e.g. protective cover 103
Housing head, for example
head section of the heat sink and/or
head section of the housing 104
Front surface of the housing head 105
Third direction, for example horizontal of a mounting rail 106
Second direction, for example vertical 107
First direction, for example horizontal or front normal 108
Front sides of the housing 109
Heat sink 110
Plate (or panel) of the heat sink, e.g. fin 110-P
Pin of the heat sink 110-S
Recess for holding a circuit carrier 111
Housing opening in the housing 112-1, 112-2, 112-3
Head dimension of the housing head 114
Height dimension of the housing 116
Recess for mounting on mounting rail 118
Depth section of the heat sink 120-1, 120-2
Height section of the heat sink 122-1, 122-2
Step or level 123-A, 123-B
Acute angle between height section and first direction 124
Flow channel,
for example, space between slats 126
Collar of the housing head 128
Fan 130
Functional unit in the housing
for example, programmable logic controller
or circuit breaker 140
Display 150
Circuit carrier, e.g. circuit board 200
Electrical heat sources 202
Contact strip 204

1. A housing for housing an electrical heat source, comprising:
a housing base of the housing, an extent of the housing base in a first direction determining a height dimension of the housing:
a housing head of the housing facing away from the housing base in a second direction, which housing head comprises a head dimension in the first direction which is at most 60 percent of the height dimension of the housing; and
a heat sink extending in the housing between the housing base and the housing head in the first direction, which heat sink is longer in the first direction than the head dimension and extends in the first direction on one side or on both sides of the housing head to a respective housing opening of the housing, through which the heat sink is in fluid connection with an environment of the housing.

2. The housing of claim 1, wherein the heat sink is exposed on one side or in each case on both sides of the housing head through the respective housing opening of the housing to the environment in the first direction and/or in the second direction.

3. The housing of claim 1, further comprising:
two opposite end faces of the housing in a third direction, which each extend to the first direction and second direction between the housing base and the housing head.

4. The housing of claim 1, wherein the head dimension is equal to or less than 50 percent of the height dimension, and/or
wherein the heat sink overlaps with the housing head in the first direction to at least half of the head dimension, and/or
wherein the length of the heat sink in the first direction is at least 150 percent of the head dimension, and/or
wherein the length of the heat sink in the first direction is at least 90 percent of the height dimension, and/or
wherein the heat sink is adjacent to the housing head or farther extends into the housing head.

5. The housing of claim 1, wherein the heat sink comprises at least one flow channel via which the housing openings of the housing are in fluid communication.

6. The housing of claim 1, wherein the housing base is reversibly or irreversibly attachable to a mounting rail.

7. The housing of claim 1, wherein the heat sink comprises at the at least one housing opening or at opposite ends in the first direction a respective depth section extending in the second direction.

8. The housing of claim 7, wherein the respective depth section of the heat sink is flush with the housing or the housing base in the first direction at one or each of the housing openings, and/or
wherein the housing or the housing base protrudes beyond the heat sink in the first direction at one or each of the housing openings.

9. The housing of claim 1, wherein the heat sink comprises a respective height section in the first direction on one side or on both sides of the housing head, which height section extends in the first direction.

10. The housing of claim 9, wherein the height section or sections of the heat sink extend parallel to the first direction, and/or
wherein the height section or sections of the heat sink extend in the first direction and in the second direction, and/or
wherein the one or more height sections of the heat sink extend in a straight line between the first direction and the second direction with an acute angle to the first direction.

11. The housing of claim 1, wherein the heat sink comprises a side section in the third direction at one end or at opposite ends, respectively, which side section is exposed to the third direction.

12. The housing of claim 7, further comprising:
a protective grid at one or each of the height sections and/or at one or each of the depth sections and/or at one or each of the side sections,
wherein the respective housing opening comprises a plurality of grid openings in the respective protective grid, through which the heat sink is in fluid communication with the environment and/or is exposed.

13. The housing of claim 12, wherein the plurality of grid openings of the protective grid correspond to or are congruent with through openings of the heat sink.

14. The housing of claim 1, further comprising:
a further housing opening in the housing base, through which the heat sink is in fluid communication with the environment of the housing and/or is exposed.

15. The housing of claim 1, wherein the heat sink comprises at least one group of mutually parallel plates and/or pins and/or wall sections.

16. The housing of claim 15, wherein the heat sink comprises a heat sink base from which the mutually parallel plates and/or pins and/or wall sections project.

17. The housing of claim 1, wherein the housing head comprises a front surface perpendicular to the second direction and a collar completely or partially circumferentially surrounding the front surface, which collar extends in the second direction between the heat sink and the front surface.

18. The housing of claim 1, wherein the heat sink comprises a head portion extending into the housing head in the second direction.

19. The housing of claim 1, further comprising:
a fan arranged in the housing head.

20. The housing of claim 1, wherein the heat sink comprises a recess configured to receive a circuit carrier comprising the electrical heat source.
